(19) United States
(12) Patent Application Publication
(10) Pub. No.: US 2022/0090292 A1
(43) Pub. Date: Mar. 24, 2022

(54) ACTIVE BALANCING SEED LIFT

(71) Applicant: Linton Crystal Technologies Corp., Rochester, NY (US)

(72) Inventor: Jesse Cameron Powers, Rochester, NY (US)

(21) Appl. No.: 17/469,031

(22) Filed: Sep. 8, 2021

Related U.S. Application Data
(60) Provisional application No. 63/136,345, filed on Jan. 12, 2021.
(60) Provisional application No. 63/081,824, filed on Sep. 22, 2020.

(51) Int. Cl. C30B 15/32; B65H 54/28; B65H 75/44; C30B 15/10; C30B 35/00

(52) U.S. Cl. CPC C30B 15/32; B65H 54/2848; B65H 2701/35; C30B 15/10; C30B 35/00; B65H 75/44

(57) ABSTRACT

A crystal growing system includes a rotating seed lift assembly to rotate and lift a seed crystal supported by a cable. The seed lift assembly includes a spool that rotates to wrap the cable around the spool, thus raising the cable. As the spool rotates, it moves in an axial direction to avoid displacing the cable in the axial direction. A leadscrew in a counterweight assembly is mechanically coupled to the spool via a coupling (e.g., a sprocket-and-chain coupling coupled to the spool spindle). As the spool rotates, the leadscrew thus rotates at a rate proportional to the spool's rate of rotation. A movable counterweight driven by the leadscrew is thus driven to move in a direction opposite the axial direction (e.g., opposite the movement of the spool). The counterweight assembly is thus configured to offset center-of-mass changes that would have otherwise been introduced by movement of the spool.

### CROSS REFERENCE TO RELATED APPLICATIONS

The present application claims the benefit of U.S. Provisional Application No. 63/081,824 filed Sep. 22, 2020 and entitled “ACTIVE BALANCING MECHANISM FOR SEED LIFTING AND ROTATING SYSTEM,” and U.S. Provisional Application No. 63/136,345 filed Jan. 12, 2021 and entitled “ACTIVE BALANCING SEED LIFT,” the disclosures of which are hereby incorporated by reference in their entirety.

### TECHNICAL FIELD

The present disclosure relates to crystal growth equipment generally and more specifically to an active balancing lift for a seed crystal.

### BACKGROUND

Large crystals, especially monocrystalline ingots, are extremely important to various fields of technology. With respect to modern electronics, monocrystalline silicon is an especially important source material used for various functions, such as wafers for integrated circuits and components of photovoltaic panels. A monocrystalline structure includes a continuous crystal lattice without grain boundaries, and can be made of a single element or of multiple elements (e.g., doped materials).

One manufacturing technique often used to create monocrystalline silicon is the Czochralski method, which involves dipping a seed crystal into a molten bath of material, then slowly pulling the seed crystal away from the molten bath while rotating the seed crystal. However, current techniques suffer from inefficiencies caused by vibration, imbalance, and other similar problems. If not performed correctly, a failure can occur and the resultant ingot may be a polycrystalline ingot, which can include grain boundaries. Since grain boundaries can be problematic for various uses, the failed ingot may have to be melted and re-grown, wasting time and energy. Since monocrystalline growth procedures often take long periods of time (e.g., on the order of tens of hours or days), any failures can have significant consequences to production efficiency.

There is a need for improved equipment for efficiently manufacturing large single crystals, such as monocrystalline silicon.

### SUMMARY

Certain aspects of the present disclosure relate to a seed lifting assembly comprising a platform base having a cable port for outputting a cable supporting a seed crystal; a spool having a helical collection groove extending along a length of the spool, the spool rotatable about an axis of rotation to wind the cable into the collection groove as the spool moves longitudinally along a spool axis; and a counterweight assembly coupled to the platform base, the counterweight assembly including: a counterweight leadscrew rotatably coupled to the spool such that rotation of the spool induces rotation of the counterweight leadscrew; and a movable counterweight coupled to the counterweight leadscrew, wherein rotation of the counterweight leadscrew induces sliding of the movable counterweight along a counterweight axis that is parallel to the spool axis; and wherein, in response to longitudinal movement of the spool in a first direction, the counterweight assembly is configured to slide the movable counterweight in a direction opposite the first direction by an amount sufficient to offset any center of mass displacement induced by the longitudinal movement of the spool.

Certain aspects of the present disclosure relate to a crystal growing system comprising a growth chamber having a crucible containing a melt; a seed crystal suspended within the growth chamber by a cable along a cable centerline; and a seed lift assembly rotatably coupled to a top end of the growth chamber and having an assembly center of mass along the cable centerline, the seed lift assembly supporting the cable within the growth chamber, the seed lift assembly having a spool for raising the cable and having a movable counterweight, the spool having a spool center of mass that moved with respect to the cable centerline as the cable is raised, the movable counterweight having a counterweight center of mass, wherein the movable counterweight is mechanically coupled to the spool such that movement of the spool center of mass with respect to the cable centerline induces coordinated movement of the counterweight center of mass such that the assembly center of mass remains along the cable centerline

Certain aspects of the present disclosure relate to a method for growing a crystal, the method comprising lowering a seed crystal to a melt by a cable supported by a seed lift assembly, the cable having a cable centerline; and simultaneously rotating the seed lift assembly and raising the cable, wherein raising the cable includes: raising the cable via movement of a component of the seed lift assembly, wherein movement of the component causes a center of mass of the component to be moved with respect to the cable centerline; and automatically moving a movable counterweight in response to movement of the component, wherein the movable counterweight is mechanically coupled to the component such that movement of the center of mass of the component with respect to the cable centerline is offset by movement of a counterweight center of mass to maintain a center of mass of the seed lift assembly along the cable centerline.

Additional implementations and/or aspects of the present disclosure will be apparent to those of ordinary skill in the art in view of the detailed description of various implementations, which is made with reference to the drawings, a brief description of which is provided below.

### BRIEF DESCRIPTION OF THE DRAWINGS

The specification makes reference to the following appended figures, in which use of like reference numerals in different figures is intended to illustrate like or analogous components.

FIG. 1 is a schematic diagram of a crystal growth system with a seed lift assembly, according to certain aspects of the present disclosure.

FIG. 2 is a graphical projection of a front of a seed lift assembly, according to certain aspects of the present disclosure.

FIG. 3 is a partial-cutaway graphical projection of a front of a seed lift assembly, according to certain aspects of the present disclosure.

FIG. 4 is a partial-cutaway rear view of a seed lift assembly showing the active balance counterweight assembly, according to certain aspects of the present disclosure.

FIG. 5 is a partial-cutaway, enlarged rear view of an active balance counterweight assembly, according to certain aspects of the present disclosure.

FIG. 6 is a graphical projection of select components of an active balance counterweight assembly, according to certain aspects of the present disclosure.

FIG. 7 is a graphical projection of a counterweight of an active balance counterweight assembly, according to certain aspects of the present disclosure.

FIG. 8 is a partial-cutaway graphical projection of the rear of a seed lift assembly, showing the spool and movable counterweight, according to certain aspects of the present disclosure.

FIG. 9 is a schematic top view of a seed lift assembly with the spool in a first spool position and the movable counterweight in a first counterweight position, according to certain aspects of the present disclosure.

FIG. 10 is a schematic top view of a seed lift assembly with the spool in a second spool position and the movable counterweight in a second counterweight position, according to certain aspects of the present disclosure.

FIG. 11 is a schematic rear view of a counterweight assembly, according to certain aspects of the present disclosure.

FIG. 12 is a flowchart depicting a process for actively balancing a seed lift, according to certain aspects of the present disclosure.

### DETAILED DESCRIPTION

Certain aspects and features of the present disclosure relate to a crystal growing system that includes a rotating seed lift assembly to rotate and lift a seed crystal supported by a cable. The seed lift assembly includes a spool that rotates to wrap the cable around the spool, thus raising the cable. As the spool rotates, it moves in an axial direction to avoid displacing the cable in the axial direction. A leadscrew in a counterweight assembly is mechanically coupled to the spool via a coupling (e.g., a sprocket-and-chain coupling). As the spool rotates, the leadscrew thus rotates at a rate proportional to the spool's rate of rotation. A movable counterweight driven by the leadscrew is thus driven to move in a direction opposite the axial direction. The counterweight assembly is thus configured to offset center-of-mass changes that would have otherwise been introduced by movement of the spool and increased mass of the spool as additional cable is wound around the spool.

Certain crystal growth techniques, such as the creation of monocrystalline silicon ingots, makes use of a seed crystal suspended above a melt of material (e.g., metalloids, such as silicon) within a sealed enclosure. The seed crystal is lowered to contact the melt, then raised and rotated in a controlled fashion to permit formation of a nascent ingot of crystallized material (e.g., the growing crystal). As the seed crystal continues to be lifted away from the surface of the melt, the nascent monocrystalline ingot continues to grow until a desired length has been reached. The seed crystal and nascent ingot can be drawn vertically up into a receiving chamber above the melt.

The crystal growing process can take different amounts of times depending on the end size of the ingot. In an example, growing of a cylindrical ingot of monocrystalline silicon to approximately 5-7 meters in length may take approximately two days. Any sufficient disturbances to the system during that time can result in significant defects in the resultant ingot, which may lead to a failed ingot. A failed ingot may need to be re-melted and re-grown, which can be very expensive. Certain aspects of the present disclosure relate to improvements that permit a seed growing system to operate with reduced shaking (e.g., of the cable) and/or other disturbances.

To achieve desirable and reproducible results with high efficiency, it can be important to provide efficient and precise control of the cable used to suspend, rotate, and raise the seed crystal and nascent ingot. A seed lift assembly positioned at the top of the receiving chamber can control the rotation and lifting of the cable. The cable can exit out from the seed lift assembly at a cable port.

To control rotation, the entire seed lift assembly is rotatably coupled to the receiving chamber so that it can be rotated around an axis of rotation. The axis of rotation can be collinear with the cable exiting the seed lift assembly (e.g., collinear with the cable in the receiving chamber). A base of the seed lift assembly is rotatably coupled to the top of the receiving chamber and driven (e.g., by a rotation motor) to rotate at a desired speed(e.g., on the order of ones or tens of revolutions per minute, such as 1-40 RPM).

The mechanisms used to raise the cable are supported by the rotating base of the seed lift assembly, and thus also rotate with respect to the receiving chamber. In some cases, the cable can be lifted by a cable winch system that includes a grooved spool or drum that collects (e.g., winds up) the cable in the groove as the spool is rotated (e.g., rotated at a speed on the order of tenths or ones of revolutions per minute). The cable winch system also axially translates the spool along its axis of rotation such that the cable does not overlap itself during the process and so the cable is not axially displaced along the spool's axis of rotation. Thus, throughout the growing process, the spool moves axially from a start position to an end position. Additionally, since additional cable is being wound around the spool as the growing process progresses, the overall combined mass of the spool and wound cable increases throughout the growing process. Thus, from the start of the growing process to the end of the growing process, the center of mass (CoM) of the spool shifts from a start location to and end location. As used herein unless otherwise indicated, the term “center of mass” as it relates to the spool refers to the center of mass of the spool and any cable wound around the spool (e.g., cable which would be axially displaced along with axial displacement of the spool).

Since the various components of the seed lift assembly have different weights, one or more static counterweights can be coupled to the base of the seed lift assembly at various locations to move the CoM of the seed lift assembly to a position aligned with a center of the cable port and/or a centerline of the cable as it exits from the cable port. In other words, a line extending axially through the center of the cable as the cable exits the cable port and passes down the receiving chamber can be known as the cable centerline. The CoM of the seed lift assembly can be positioned somewhere along this line, such as at a location above the center of the cable port.

However, because of the movement of the CoM of the spool while the cable is being raised, the CoM of the seed lift assembly would normally tend to vary away from the cable centerline during the course of the growing process. If the CoM of the seed lift assembly does not match the cable centerline and/or does not fall on the axis of rotation of the seed lift assembly, vibrations and undesirable orbits can be induced in the cable. Therefore, according to certain aspects and features of the present disclosure, an active counterweight system can be used to offset movement of the spool's CoM such that the CoM of the entire seed lift assembly remains aligned with the cable centerline and/or the seed lift assembly's axis of rotation.

The active counterweight can be mechanically coupled to the spool such that rotation of the spool—and thus axial movement of the CoM of the spool—automatically induces movement of a movable counterweight, thus moving the CoM of the movable counterweight. This mechanical coupling can ensure the CoM of the counterweight is always moved at precisely the correct amount to offset the CoM of the spool.

In some cases, the mechanical coupling can include a sprocket-and-chain coupling, although that need not always be the case. A sprocket located on the spindle that drives the spool can be coupled (e.g., via a chain) to a corresponding sprocket on a leadscrew that drives the counterweight. Thus, rotation of the spool will necessarily include rotation of the spool's spindle, which in turn rotates the leadscrew, which in turn drives the counterweight.

In some cases, the counterweight can be a block that is slidably supported in a channel, such as by a set of wheels. The counterweight can be driven using any suitable mechanical actuator, such as a leadscrew that engages a nut on the counterweight, such that rotation of the leadscrew in one direction or another causes the counterweight to slide within the channel in a first axial direction or second axial direction. Other mechanical actuators can be used. As used herein, mechanical actuators can include any type of actuator that can be driven without the use of electricity. For example, in some cases, a mechanical actuator can include a hydraulic actuator, a pneumatic actuator, a magnetic actuator, a rigid belt or rigid chain actuator, and/or other such actuators. In an example, a hydraulic actuator can be used by having axial movement of the spool engage a first hydraulic piston that pressurizes a hydraulic fluid into a second hydraulic piston that induces movement of the counterweight. In such an example, the sizes of the first and second hydraulic pistons (e.g., piston head areas) can be adjusted such that the counterweight moves a distance that is proportional to movement of the spool such that the CoM of the seed lift assembly remains at a desired location.

In a first example seed lift assembly, a spool can have a pitch diameter (e.g., diameter between the center of the cable across opposite sides of the spool) of at or approximately 154 mm and a pitch (e.g., distance between the center of the cable at sequential wraps) of at or approximately 8 mm. The pitch also equals the distance the spool travels axially in a full rotation. In this example, the spool can have a weight of at or approximately 13.1 kg and the movable counterweight can have a weight at or approximately 9.26 kg, providing a ratio of counterweight weight to spool weight of at or approximately 0.707. The total weight of the seed lift assembly can be at or approximately 176.5 kg, with all of the rotating components weighing at or approximately 163.4 kg.

The spool can have a maximum travel distance of at or approximately 159.5 mm. The counterweight can have a maximum travel distance of at or approximately 189 mm. Thus, the ratio of maximum spool travel to maximum counterweight travel is at or approximately 0.844. Therefore, to achieve a desirable result, it can be important to establish an actual ratio between spool travel and weight travel that is near, but greater than 0.844.

In a first example configuration, the counterweight system can include a 40-tooth spool sprocket coupled to a 26-tooth counterweight sprocket (e.g., a spool to counterweight sprocket ratio of 1.5385) attached to a leadscrew with a lead of at or approximately 6 mm, which can result in a ratio of spool travel to counterweight travel of 0.867.

In a second example configuration, the counterweight system can include a 40-tooth spool sprocket coupled to an 18-tooth counterweight sprocket (e.g., a spool to counterweight sprocket ratio of 2.2222) attached to a leadscrew with a lead of at or approximately 4 mm, which can result in a ratio of spool travel to counterweight travel of 0.900.

In a third example configuration, the counterweight system can include a 30-tooth spool sprocket coupled to a 19-tooth counterweight sprocket (e.g., a spool to counterweight sprocket ratio of 1.5789) attached to a leadscrew with a lead of at or approximately 6 mm, which can result in a ratio of spool travel to counterweight travel of 0.844.

In a second example seed lift assembly, the spool can have a weight of at or approximately 13.1 kg and the movable counterweight can have a weight at or approximately 7 kg, providing a ratio of counterweight weight to spool weight of at or approximately 0.534. The spool can have a maximum travel distance of at or approximately 159.5 mm. The counterweight can have a maximum travel distance of at or approximately 242 mm. Thus, the ratio of maximum spool travel to maximum counterweight travel is at or approximately 0.659. Therefore, to achieve a desirable result, it can be important to establish an actual ratio between spool travel and weight travel that is near, but greater than 0.659.

In a first example configuration, the counterweight system can include a 60-tooth spool sprocket coupled to a 30-tooth counterweight sprocket (e.g., a spool to counterweight sprocket ratio of 2) attached to a leadscrew with a lead of at or approximately 6 mm, which can result in a ratio of spool travel to counterweight travel of 0.667.

In a second example configuration, the counterweight system can include a 36-tooth spool sprocket coupled to an 18-tooth counterweight sprocket (e.g., a spool to counterweight sprocket ratio of 2) attached to a leadscrew with a lead of at or approximately 6 mm, which can result in a ratio of spool travel to counterweight travel of 0.667.

In a third example configuration, the counterweight system can include a 54-tooth spool sprocket coupled to an 18-tooth counterweight sprocket (e.g., a spool to counterweight sprocket ratio of 3) attached to a leadscrew with a lead of at or approximately 4 mm, which can result in a ratio of spool travel to counterweight travel of 0.667.

In a third example seed lift assembly, the spool can have a weight of at or approximately 13.1 kg and the movable counterweight can have a weight at or approximately 17 kg, providing a ratio of counterweight weight to spool weight of at or approximately 1.298. The spool can have a maximum travel distance of at or approximately 159.5 mm. The counterweight can have a maximum travel distance of at or approximately 100 mm. Thus, the ratio of maximum spool travel to maximum counterweight travel is at or approximately 1.595. Therefore, to achieve a desirable result, it can be important to establish an actual ratio between spool travel and weight travel that is near, but greater than 1.595.

In a first example configuration, the counterweight system can include a 30-tooth spool sprocket coupled to a 24-tooth counterweight sprocket (e.g., a spool to counterweight sprocket ratio of 2) attached to a leadscrew with a lead of at or approximately 4 mm, which can result in a ratio of spool travel to counterweight travel of 1.600.

In a second example configuration, the counterweight system can include a 35-tooth spool sprocket coupled to a 28-tooth counterweight sprocket (e.g., a spool to counterweight sprocket ratio of 2) attached to a leadscrew with a lead of at or approximately 4 mm, which can result in a ratio of spool travel to counterweight travel of 1.600.

In a third example configuration, the counterweight system can include a 30-tooth spool sprocket coupled to an 18-tooth counterweight sprocket (e.g., a spool to counterweight sprocket ratio of 3) attached to a leadscrew with a lead of at or approximately 3 mm, which can result in a ratio of spool travel to counterweight travel of 1.600.

To achieve desired results, the ratio between the amount of displacement of the counterweight and the amount of displacement of the spool can be based on the mass of the spool (e.g., the spool's empty mass), the mass of the cable wound around the spool, and the mass of the counterweight. For example, for a heavier spool, the counterweight can be increased in mass and/or the displacement ratio can adjusted. The displacement ratio can be achieved based on a gear ratio between a spool sprocket and a counterweight sprocket and a pitch of the counterweight leadscrew. Any of these variables (e.g., masses, ratios, distances, pitches, and the like) can be set first. For example, in some cases, the mass of the spool, mass of the cable, and distance of travel of the spool can be set, in which case the distance in travel of the counterweight and/or mass of the counterweight can be calculated based on the set variables. In another example, the mass of the cable and mass of the counterweight can be set, and the mass of the spool may be calculated based on the set variables. In another example, the desired displacement ratio can be set and the gear ratio and/or leadscrew pitch can be calculated to achieve the desired displacement ratio.

While described herein with reference to a winch-based lift system, certain aspects and features of the present disclosure can be used to offset movement of CoM of any movable component of a seed lift assembly, including other styles of seed lifting mechanisms.

These illustrative examples are given to introduce the reader to the general subject matter discussed here and are not intended to limit the scope of the disclosed concepts. The following sections describe various additional features and examples with reference to the drawings in which like numerals indicate like elements, and directional descriptions are used for illustrative purposes, but should not be used to limit the present disclosure. The elements included in the illustrations herein may not be drawn to scale.

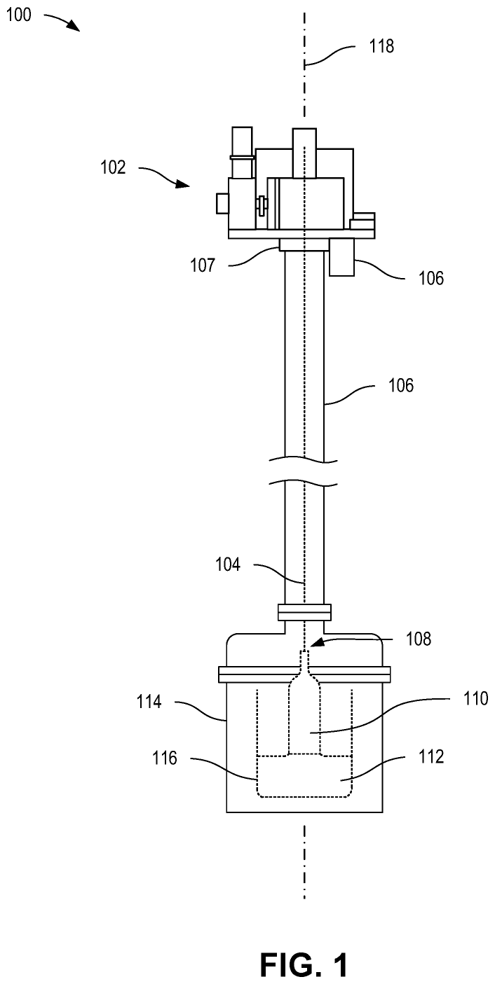

FIG. 1 is a schematic diagram of a crystal growth system 100 with a seed lift assembly 102, according to certain aspects of the present disclosure. The crystal growth system 100 can be used to grow any suitable crystals, such as monocrystalline silicon-based crystals. The crystal growth system 100 can include a furnace tank 114 containing a crucible 116 therein. The furnace tank 114 can provide heat to the crucible 116. The crucible 116 may be initially filled with solid material, which can be heated until it forms a melt 112. The crucible 116 can be controlled to rotate in a first direction.

A receiving chamber 106 can be coupled to the top of the furnace tank 114. The receiving chamber 106 can extend for any suitable length. A seed lift assembly 102 can be coupled to the top end of the receiving chamber 160. The seed lift assembly 102 can be rotatably coupled to the top end of the receiving chamber 106, such as via a bearing 107. A rotation motor 106 can control rotation of the seed lift assembly 102 about an axis of rotation 118 that passes axially through the center of the receiving chamber 160 (and axially through a centerline of the cable within the receiving chamber 160).

The seed lift assembly 102 can suspend a cable 104 down through the receiving chamber 106 and into the furnace tank 114. At a distal end of the cable 104 (e.g., the end furthest from the seed lift assembly 102) is held a seed crystal 108. The seed crystal can be a small, single crystal of the same material as the melt 112.

The crystal growth system 100 is depicted between the start and end of a growing process. At the beginning of the growing process, the seed lift assembly 102 can lower the cable 104 until the seed crystal 108 contacts the melt 112. The seed lift assembly 102 can then steadily raise the seed crystal 108 (e.g., at a speed on the order of ones, tens, or hundreds of millimeters per hours, such as 0-600 mm/hr) while allowing a nascent ingot 110 to form. To obtain optimal crystal growth, the seed lift assembly 102 can rotate in a direction opposite the direction of rotation of the crucible 116 while simultaneously raising the cable 104. As the cable 104 is raised, the nascent ingot 110 is pulled out of the melt 112, allowing new material to solidify at the bottom of the nascent ingot 110 in alignment with the monocrystalline structure of the nascent ingot 110.

During the growing process, the seed lift assembly 102 will raise the cable 104, and thus the nascent ingot 110, up into the receiving chamber 106 until the growing process ends. The growing process can end when the nascent ingot 110 reaches a desired length, when the material in the crucible 116 is expended, when the seed lift assembly 102 can no longer raise the cable 104 any further, or otherwise.

For illustrative purposes, the seed lift assembly is depicted without a covering or shroud. In some cases, a covering or shroud can surround the seed lift assembly to help maintain the desired environment within the receiving chamber 106 and furnace tank 114. The covering or shroud can keep out dust and contaminants, while permitting the gaseous environment surrounding the nascent ingot 110 to be controlled.

As disclosed in further detail herein, the seed lift assembly 102 can include an active counterbalance that maintains the center of mass of the seed lift assembly 102 along the axis of rotation 118.

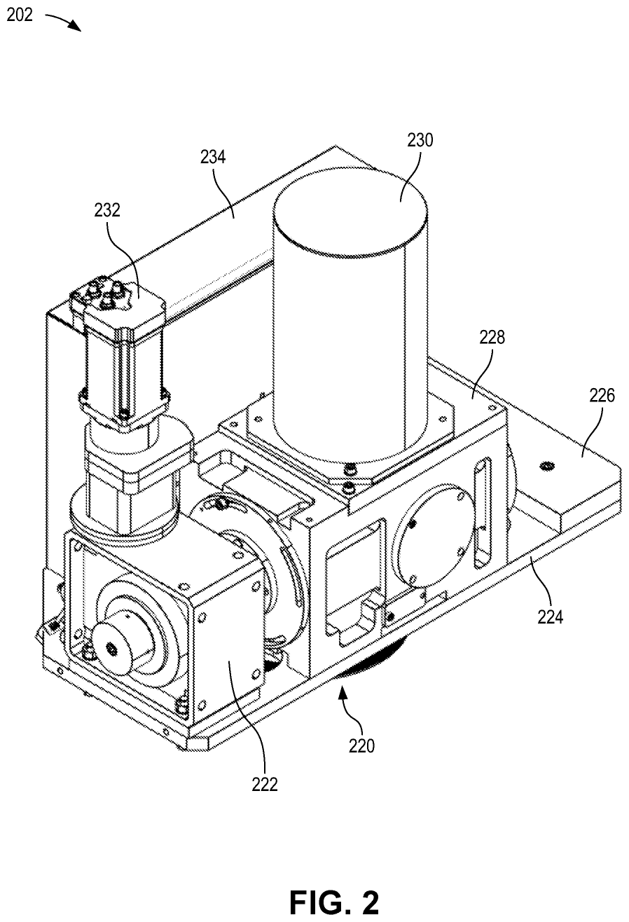

FIG. 2 is a graphical projection of a front of a seed lift assembly 202, according to certain aspects of the present disclosure. The seed lift assembly 202 can be any suitable seed lift assembly, such as seed lift assembly 102 of FIG. 1. The seed lift assembly 202 can include a base plate 224 upon which various components can be mounted. The cable can exit out a cable port 220 on the underside of the base plate 224.

The seed lift assembly 202 can include a spool located within a spool housing 228. The cable can wrap around the spool, allowing the spool to control lowering and raising of the cable via rotation. The cable can unwrap from the spool and pass upwards and around a pulley within the cable pulley assembly 230 before passing back downwards and out the cable port 220. The pulley within the cable pulley assembly 230 can facilitate maintaining the cable at the center of the cable port 220.

Rotation of the spool can be controlled by a spool motor 232. The spool motor 232 can drive a gearbox 222 that in turn drives a spool spindle that drives rotation of the spool. For example, the spool spindle can be rotationally fixed to the spool such that rotation of the spool spindle induces corresponding rotation of the spool.

An electronics enclosure 234 can be located on the base plate 224 to house electronics used to control and monitor the components of the seed lift assembly 202. As described herein, it can be useful to maintain a center of balance of the seed lift assembly 202 at a center of the cable port 220. Thus, because of the presence of heavy equipment (e.g., the spool motor 232, spool gearbox 222, and portions of the spool housing 228) on one side of the base plate 224, one or more static counterweights 226 can be located on the opposite side of the base plate 224.

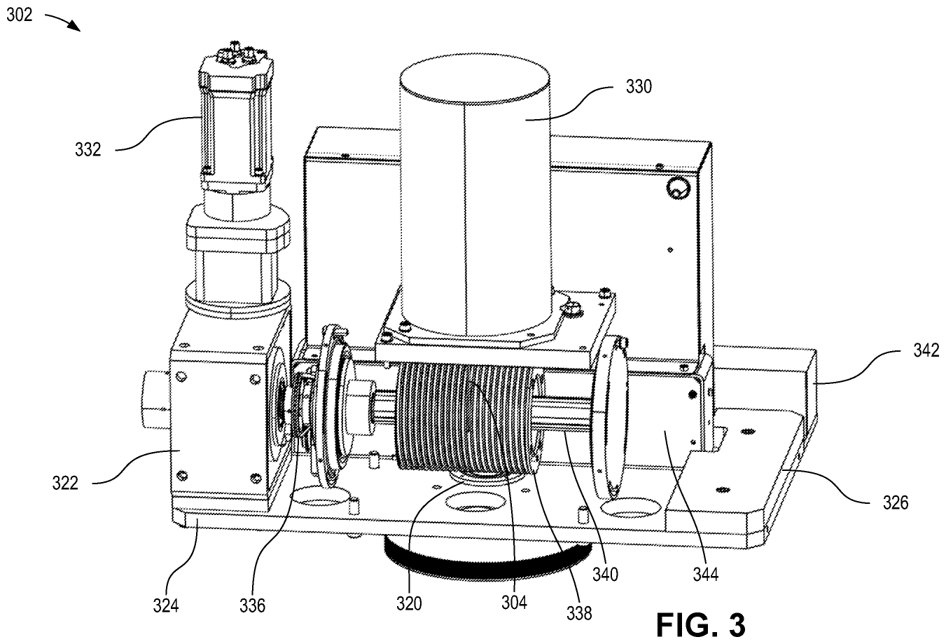

FIG. 3 is a partial-cutaway graphical projection of a front of a seed lift assembly 302, according to certain aspects of the present disclosure. The seed lift assembly 302 can be any suitable seed lift assembly, such as seed lift assembly 102 of FIG. 1. As depicted in FIG. 3, some components, such as the spool housing, are not depicted for illustrative purposes.

The spool 338 is driven by the spool spindle 340, which is driven by the spool gearbox 322, which is in turn driven by the spool motor 332. As the spool spindle 340 turns to rotate the spool 338, the spool spindle can also rotate a spool sprocket 336. The spool sprocket can mechanically couple the spool to a movable counterweight within the counterweight assembly 334 such that axial translation of the spool 338 along the spool spindle 340 induces corresponding axial translation of the counterweight in an opposite direction.

A cable 304 is depicted exiting a groove of the spool 338 and entering the cable pulley assembly 330 before being directed downwards and out the cable port 320.

Additionally, the seed lift apparatus 302 of FIG. 3 includes a base plate 324 having a first static counterweight 326 and a second static counterweight 342. The first and second static counterweights 326, 342 can act as a stationary counterbalance to the stationary components of the seed lift apparatus 302. As the center of balance of the spool 338 is moved in a first direction (e.g., from right to left as depicted in FIG. 3), a movable counterweight of the counterweight assembly 334 can move in an opposite direction (e.g., from left to right as depicted in FIG. 3) to counterbalance the spool 338.

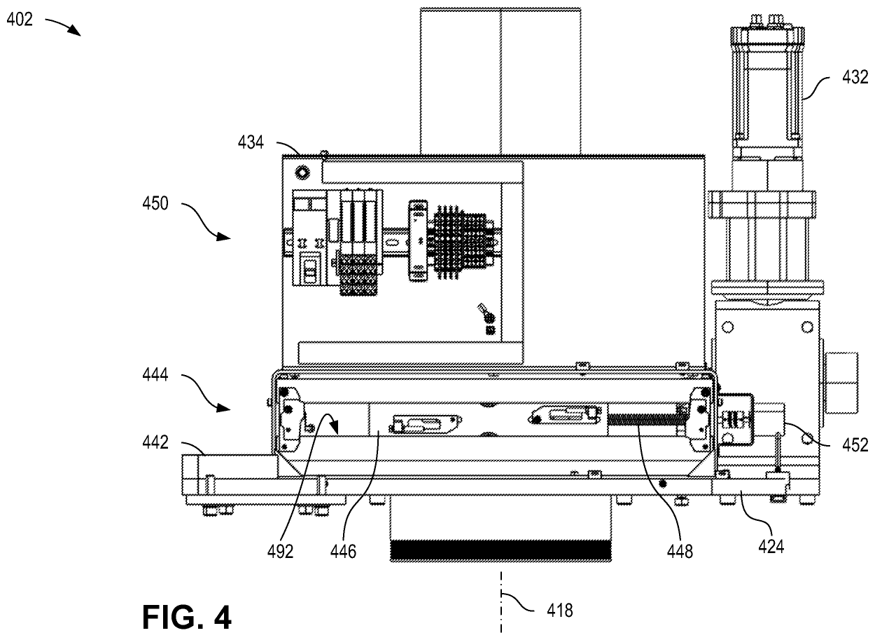

FIG. 4 is a partial-cutaway rear view of a seed lift assembly 402 showing the active balance counterweight assembly 444, according to certain aspects of the present disclosure. The seed lift assembly 402 can be any suitable seed lift assembly, such as seed lift assembly 102 of FIG. 1. Coverings of the housings of the electronics enclosure 434 and counterweight assembly 444 are not depicted for illustrative purposes.

Electronics assembly 434 can include electronics 450 used to control and/or monitor the seed lift apparatus 402. In some cases, the counterweight assembly 444 can be located underneath the electronics assembly 434. The counterweight assembly 444 can be coupled directly to the base plate 424, although that need not always be the case. However, it can be desirable to maintain the center of mass of the counterweight 446 closer to the base plate 424 rather than further spaced apart from the base plate 424.

The counterweight assembly 444 can include a counterweight driven by a leadscrew 448. The counterweight 446 can be driven to move axially (e.g., axially in a direction of the axis of the leadscrew 448). The counterweight 446 can be slidably mounted within a channel 492. As disclosed in further detail herein, movement of the spool (e.g., as driven by spool motor 432) can cause the leadscrew 448 to rotate, thus inducing axial movement of the counterweight 446.

In some cases, an encoder 452 can be optionally coupled to the leadscrew 448, such as to monitor rotation of the leadscrew 448. Monitoring rotation of the leadscrew 448 can provide insight into the position of the counterweight 446, position of the spool, and position of the cable (and thus the nascent ingot). By coupling the encoder 452 to the leadscrew 448 instead of to the spool spindle, the center of mass of the encoder 452 may be able to be located closer to the axis of rotation 418, thus reducing the overall amount of static counterweight (e.g., counterweight 442) needed to offset the mass of the encoder 452.

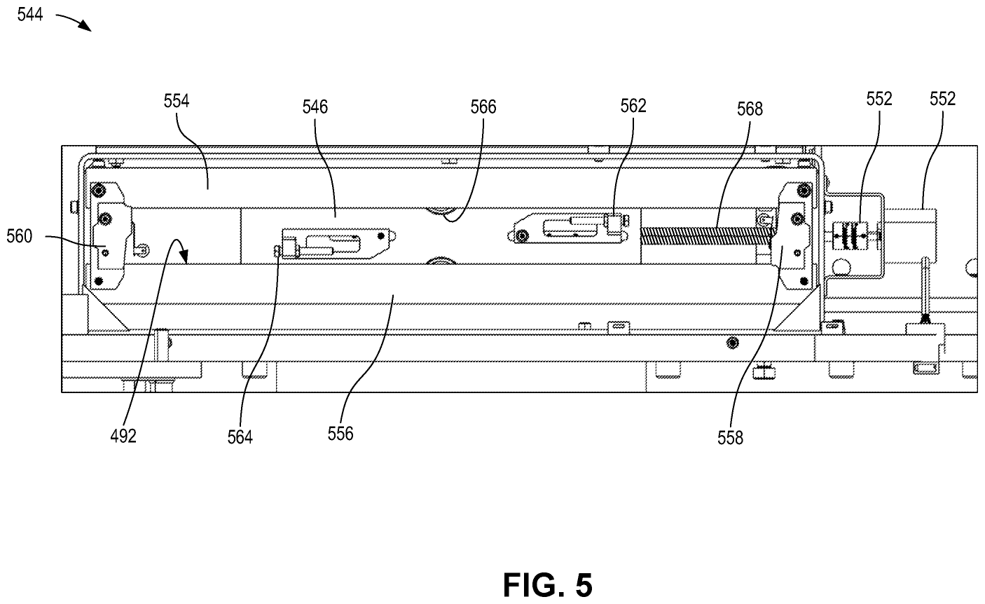

FIG. 5 is a partial-cutaway, enlarged rear view of an active balance counterweight assembly 544, according to certain aspects of the present disclosure. The counterweight assembly 544 can be any suitable counterweight assembly, such as counterweight assembly 444 of FIG. 4.

The counterweight assembly 544 can include a counterweight 546 located (e.g., slidably located) within a channel 492 of the housing of the counterweight assembly 544. While use of a channel 492 is depicted in FIG. 4, other techniques can be used to restrict undesired movement (e.g., non-axial movement) of the counterweight 546, such as stabilizing bars, carriages, and the like.

The channel 492 can be formed from various walls of the housing of the counterweight assembly 544. In some cases, at least one wall (e.g., the rear wall, or the wall coplanar with the page in FIG. 5 and facing out of the page) can include a split or opening, such as an opening between an upper wall portion 554 and a lower wall portion 556. Such a split wall can facilitate access to the counterweight 546, if needed.

Additionally, such a split wall can permit endstops 562, 564 to be coupled to the counterweight 546 and extend past the upper wall portion 554 and lower wall portion 556. Each of the endstops 562, 564 can include an adjustable stop coupled to the counterweight 546 via a block. Each endstop 562, 564 can engage respective limit switches 558, 560 adjacent opposite ends of the channel 492. In some cases, limit switches 558, 560 can be positioned elsewhere, such as within the channel 492, in which cases the limit switches 558, 560 may be engaged by the counterweight 546 itself. However, by using the endstops 562, 564 and limit switches 558, 560 depicted in FIG. 5, the extent of travel of the counterbalance 546—and thus the extent of travel of the spool and extent of travel of the cable—can be controlled by adjusting the position of the desired endstop 562, 564 (e.g., via adjustment of the adjustable stop within the block and/or adjustment of the block on the counterbalance 546).

To facilitate smooth slidable motion, the counterbalance 546 can include one or more wheels 566. Wheels 566 can engage various walls of the channel 492, such as the upper wall portion 554 and lower wall portion 556. In some cases, other friction-reducing techniques can be used in addition to or instead of wheels 566.

Encoder 552 can be coupled to the lead screw 568 via a coupling 553 (e.g., an axial shaft coupling).

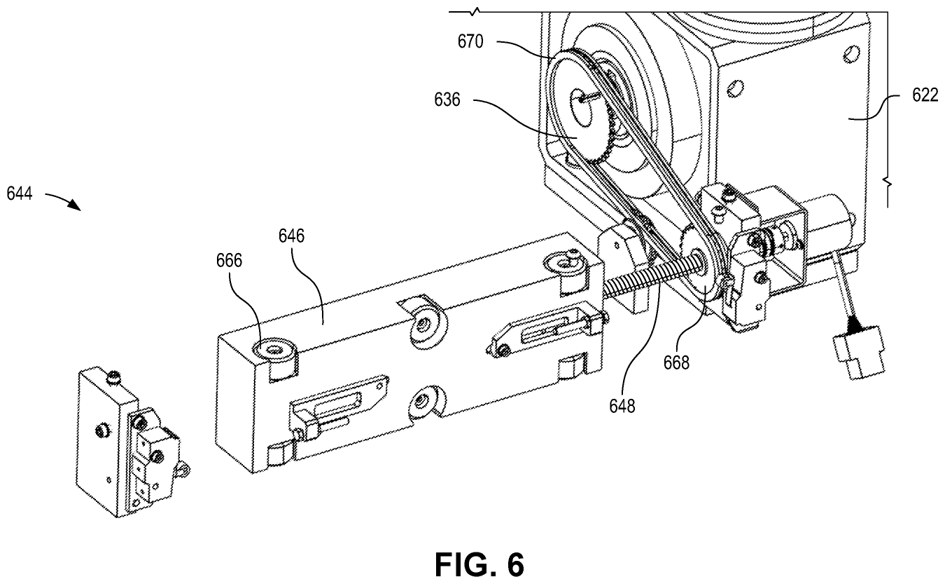

FIG. 6 is a graphical projection of select components of an active balance counterweight assembly 644, according to certain aspects of the present disclosure. The counterweight assembly 544 can be any suitable counterweight assembly, such as counterweight assembly 444 of FIG. 4. Various components of the seed lift assembly are not depicted for illustrative purposes. With the housing of the counterweight assembly 644 not depicted, the counterweight 646 can be seen in greater detail, including its wheels 666.

As the spool motor drives the spool gearbox 622, the spool gearbox 622 drives the spool spindle, which in turn rotates the spool. The spool can be coupled to the counterweight 646 such that rotation of the spool, and thus axial movement of the spool, drives corresponding opposite movement of the counterweight 646.

While various techniques can be used to mechanically couple together the spool and the counterweight 646, a sprocket-and-chain technique is depicted in FIG. 6. Rotation of the spool spindle by the spool gearbox 622 rotates both the spool and the spool sprocket 636. The spool sprocket 636 can be rotationally coupled to the leadscrew 648 via a chain 670 coupling the spool sprocket 636 to a counterbalance sprocket 668. The spool sprocket 636 can be rotationally fixed with respect to the spool spindle and the counterbalance sprocket 668 can be rotationally fixed with respect to the leadscrew 648. Thus, rotation of the spool spindle induces corresponding rotation of the leadscrew 648. The ratio of revolutions per minute of the spool spindle—and thus the spool—to the leadscrew 648 can be defined by the size ratios of the spool sprocket 636 and the counterbalance sprocket 668.

For example, a spool sprocket 636 having a size of 40 teeth and a counterbalance sprocket 668 having a size of 18 teeth can result in a ratio of 0.45. Thus, for every 0.450 revolutions of the spool spindle, and thus the spool, the leadscrew 648 can rotate 1 revolution. Depending on the lead of the leadscrew 648 (e.g., the pitch of the leadscrew 648 if a single-start leadscrew), the axial displacement of the counterbalance 646 can be calculated for each rotation of the spool spindle. In the above example, if the lead of the leadscrew 648 is 4 mm, then each rotation of the spool spindle would result in a corresponding 8.889 mm axial displacement of the counterbalance 646.

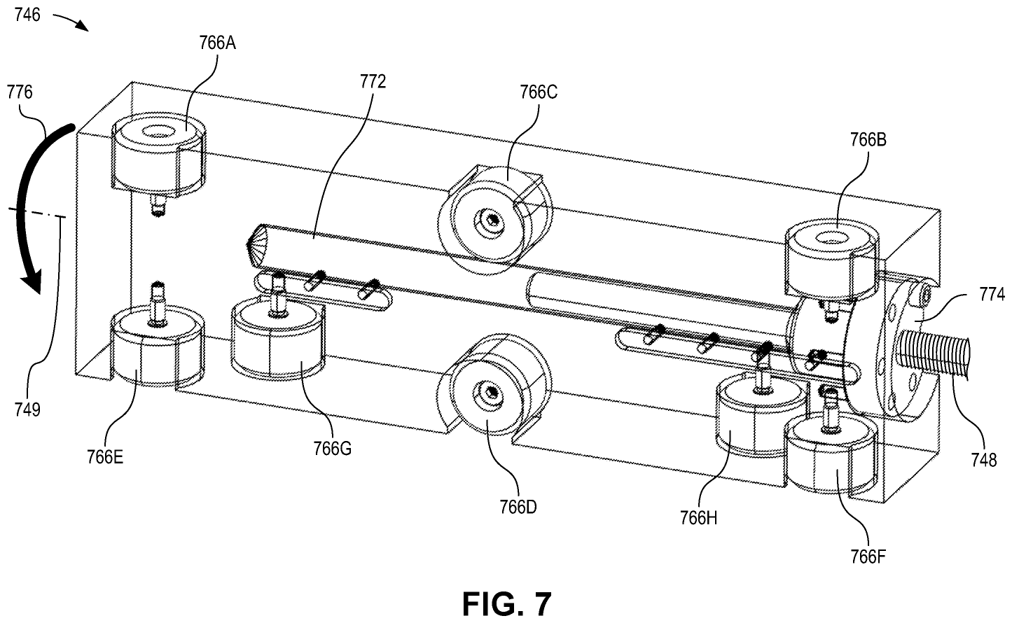

FIG. 7 is a graphical projection of the rear side of a counterweight 746 of an active balance counterweight assembly, according to certain aspects of the present disclosure. The counterweight 746 can be any suitable counterweight, such as counterweight 446 of FIG. 4. For illustrative purposes, counterweight 446 is depicted as transparent.

Counterweight 746 can be of any suitable shape, although in some cases a rectangular shape is used. The counterweight 746 can include a number of wheels 766A, 766B, 766C, 766D, 766E, 766F, 766G, 766H. Any number can be used, but in some cases eight wheels are used. Wheels 766A, 766B can be positioned on a top rear side at opposite ends of the counterweight 746 from one another. Wheels 766A, 766B can engage the upper wall portion of the channel (e.g., upper wall portion 554 of FIG. 5). Corresponding wheels 766E, 766F can be positioned on a bottom rear side at opposite ends of the counterweight 746 from one another. Wheels 766E, 766F can engage the lower wall portion of the channel (e.g., lower wall portion 556 of FIG. 5). Wheels 766C, 766D can be positioned on respective top and bottom sides of the counterweight 746, to engage corresponding surfaces in the channel.

Wheels 766G, 766H can be positioned on the bottom front side of the counterweight 746 at opposite ends of the counterweight 746 from one another. In some cases, no wheels are used at the top front side of the counterweight 746. Because of the direction of rotation of the leadscrew 746 during the growing process (e.g., while the nascent ingot is being formed), the counterweight 746 would be urged to rotate in direction 776 about the axis 749 of the leadscrew 748. When being urged to rotate in direction 776, wheels 766G, 766H would be pushed against the corresponding wall of the channel, while the top front side of the counterweight 746 would be urged away from that wall. Thus, smooth operation can be ensured when smooth operation is most needed (e.g., while the nascent ingot is being formed and the cable is being lifted), while also reducing the total number of wheels used by excluding some wheels that would be only used when smooth operation is not as significant a concern (e.g., while the cable is being lowered towards the melt). Additionally, the ability to use fewer wheels can facilitate reducing the overall size of the counterweight 746 (e.g., because the counterweight 746 material is denser than a wheel, any volume not occupied by a wheel can be occupied by counterweight material, and thus fewer cutouts or openings for wheels can permit the same amount of mass to fit in a slightly smaller volume).

To drive the counterweight 746, leadscrew 748 can interact with nut 774. Nut 774 can be rotationally fixed to the counterweight 746. A cavity 772 within the counterweight can extend through some or all of the counterweight 746 and have a diameter greater than the diameter of the leadscrew 748, thus permitting the counterweight 746 to move up (e.g., proximally) along the leadscrew 748. As the leadscrew 748 is rotated, the nut 774 is held rotationally fixed to the counterweight 746, which is in turn held substantially rotationally fixed with respect to the channel. Thus, rotation of the leadscrew 748 causes the nut 774 to move up (e.g., proximally) or down (e.g., distally) along the leadscrew 748.

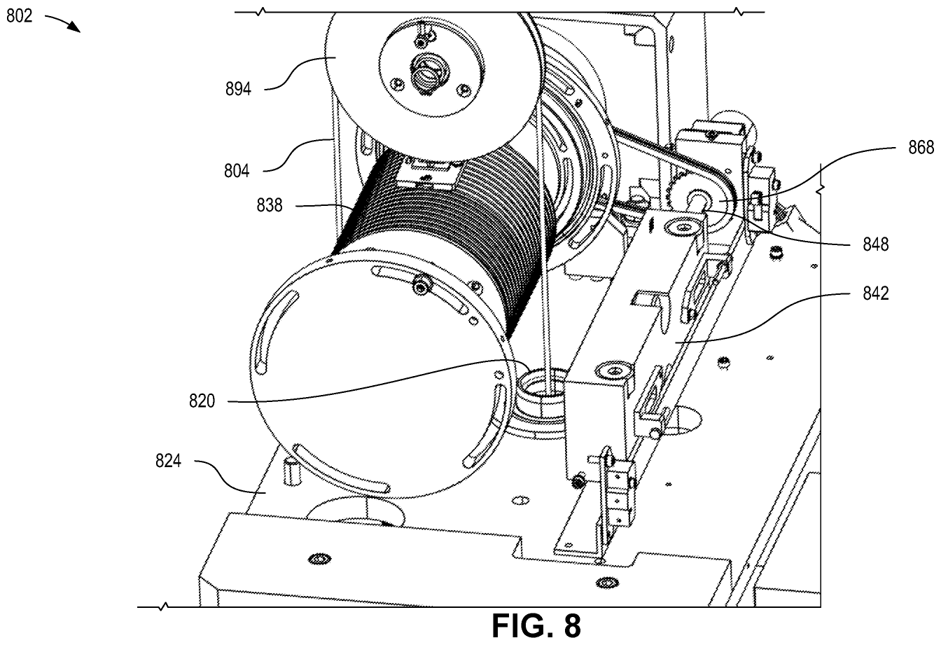

FIG. 8 is a partial-cutaway graphical projection of the rear of a seed lift assembly 802, showing the spool 838 and movable counterweight 842, according to certain aspects of the present disclosure. The seed lift assembly 802 can be any suitable seed lift assembly, such as seed lift assembly 102 of FIG. 1. Certain components of the seed lift assembly 802 are not depicted for illustrative purposes.

Cable 804 is seen being wound onto spool 838. Cable 804 can enter the seed lift assembly 802 through the base plate 824 via cable port 820. The cable 804 can pass up and over the pulley 894 before being directed back down and into a groove of the spool 838. Thus, as the spool 838 rotates, the cable is gradually wound around the spool 838. Cable port 820 can align with axis of rotation of the seed lift assembly 802 and the center of mass of the seed lift assembly 802.

As the spool 838 rotates, it also translates axially (e.g., into the page as seen in FIG. 8). Also, as the spool 838 rotates, it causes the leadscrew 848 of the counterweight assembly to rotate via counterweight sprocket 868. Rotation of the leadscrew 848 thus induces axial movement of the counterweight 842 in a direction opposite the spool 838 (e.g., out of the page as seen in FIG. 8), thus offsetting any CoM displacement that would have otherwise been induced by movement of the spool 838.

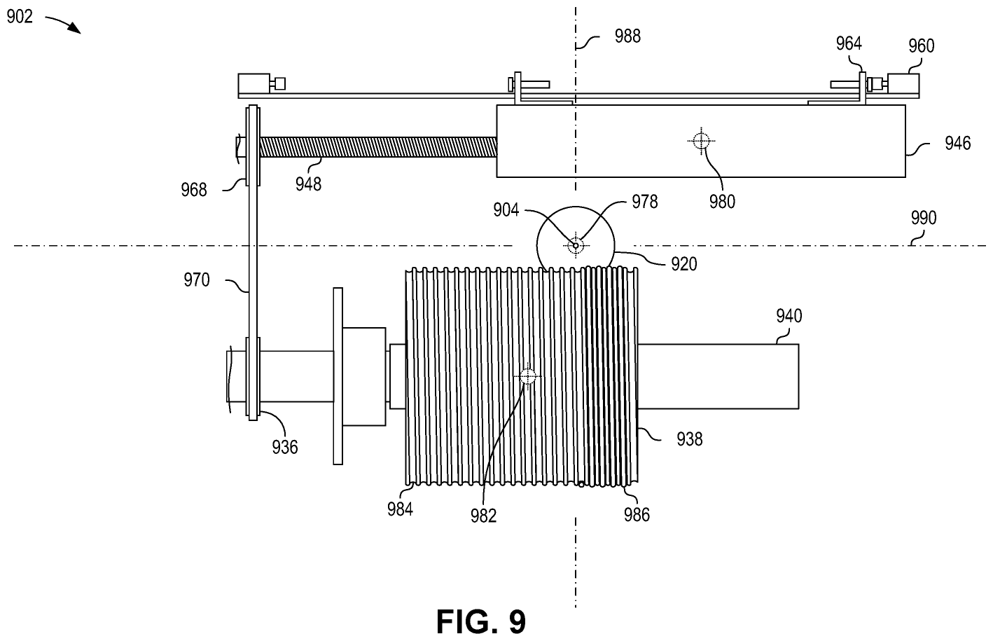

FIG. 9 is a schematic top view of a seed lift assembly 902 with the spool 938 in a first spool position and the movable counterweight 946 in a first counterweight position, according to certain aspects of the present disclosure. The seed lift assembly 902 can be any suitable seed lift assembly, such as seed lift assembly 102 of FIG. 1. In some cases, the first spool position and first counterweight position can correspond with a start spool position and start counterweight position at the beginning of a crystal growing process (e.g., at the start of raising the cable from the melt). A cable 904 can enter the seed lift assembly 902 via cable port 920.

A lateral centerline 988 (or lateral plane) of the seed lift assembly 902 can be defined as a line (or plane) extending through the center of the cable port 920 (e.g., and through the center of mass 978 of the seed lift assembly 902) and perpendicular to the axis of the spool spindle 940. The lateral centerline 988 (or lateral plane) can separate the seed lift assembly 902 into a “left” side and a “right” side as depicted in FIG. 9.

A longitudinal centerline 990 (or longitudinal plane) of the seed lift assembly 902 can be defined as a line (or plane) extending through the center of the cable port 920 (e.g., and through the center of mass 978 of the seed lift assembly 902) and parallel to the axis of the spool spindle 940. The longitudinal centerline 988 (or longitudinal plane) can separate the seed lift assembly 902 into a “top” side and a “bottom” side as depicted in FIG. 9.

In the first spool position, spool 938 is positioned proximally along spool spindle 940. The spool 938 includes a few rotations of wound cable 986 in its grooves 984. The spool center of mass 982 is depicted, and rests to the left of the lateral centerline 988 and to the bottom of the longitudinal centerline 990.

In the first counterweight position, counterweight 946 is located distally along the leadscrew 948. In some cases, in the first counterweight position, a first endstop 964 can engage a first limit switch 960. The counterweight center of mass 980 is depicted, and rests to the right of the lateral centerline 988, or on an opposite side of the lateral centerline 988 from the spool center of mass 982. The counterweight center of mass 980 rests to the top of the longitudinal centerline 990, or on an opposite side of the longitudinal centerline 990 from the spool center of mass 982.

As the spool 938 is rotated to wind up additional cable 904, it will move distally along the spool spindle 940 (e.g., from left to right as seen in FIG. 9). The spool center of mass 982 will move towards the lateral centerline 988, and in some cases, move past the lateral centerline 988. As the spool 938 rotates, the spool sprocket 936 rotates and causes the chain 970 to rotate the counterweight sprocket 968, which in turn rotates the lead screw 948 to drive the counterweight 946 to move axially in a direction opposite the spool 938 (e.g., the counterweight 946 can move from right to left as seen in FIG. 9). The counterweight center of mass 980 will move towards the lateral centerline 988, and in some cases, move past the lateral centerline 988. In some cases, when the spool center of mass 982 reaches the lateral centerline 988, the counterweight center of mass 980 will also reach the lateral centerline 988 although that need not always be the case.

Thus, as the spool center of mass 982 moves with respect to the center of the cable port 920, the counterweight center of mass 980 moves in a corresponding, opposite direction to maintain the center of mass 978 of the seed lift assembly 902 in the same location (e.g., at or above the center of the cable port 920 and/or along an axis of rotation of the seed lift assembly 902).

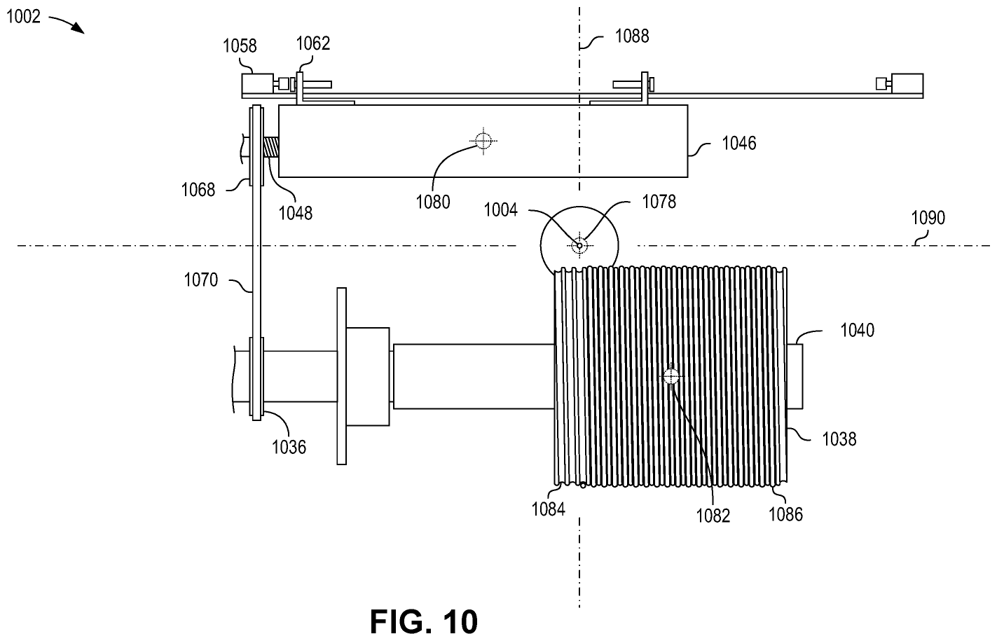

FIG. 10 is a schematic top view of a seed lift assembly with the spool in a second spool position and the movable counterweight in a second counterweight position, according to certain aspects of the present disclosure. The seed lift assembly 1002 can be any suitable seed lift assembly, such as seed lift assembly 102 of FIG. 1. In some cases, the second spool position and second counterweight position can correspond with an end spool position and end counterweight position at the end of a crystal growing process (e.g., after the cable has been raised to its highest set point). A cable 1004 can enter the seed lift assembly 1002 via cable port 1020.

A lateral centerline 1088 (or lateral plane) of the seed lift assembly 1002 can be defined as a line (or plane) extending through the center of the cable port 1020 (e.g., and through the center of mass 1078 of the seed lift assembly 1002) and perpendicular to the axis of the spool spindle 1040. The lateral centerline 1088 (or lateral plane) can separate the seed lift assembly 1002 into a “left” side and a “right” side as depicted in FIG. 10.

A longitudinal centerline 1090 (or longitudinal plane) of the seed lift assembly 1002 can be defined as a line (or plane) extending through the center of the cable port 1020 (e.g., and through the center of mass 1078 of the seed lift assembly 1002) and parallel to the axis of the spool spindle 1040. The longitudinal centerline 1088 (or longitudinal plane) can separate the seed lift assembly 1002 into a “top” side and a “bottom” side as depicted in FIG. 10.

In the second spool position, spool 1038 is positioned distally along spool spindle 1040. The spool 1038 includes numerous rotations of wound cable 1086 in its grooves 1084. The spool center of mass 1082 is depicted, and rests to the right of the lateral centerline 1088 and to the bottom of the longitudinal centerline 1090.

In the second counterweight position, counterweight 1046 is located proximally along the leadscrew 1048. In some cases, in the second counterweight position, a second endstop 1062 can engage a second limit switch 1058. The counterweight center of mass 1080 is depicted, and rests to the left of the lateral centerline 1088, or on an opposite side of the lateral centerline 1088 from the spool center of mass 1082. The counterweight center of mass 1080 rests to the top of the longitudinal centerline 1090, or on an opposite side of the longitudinal centerline 1090 from the spool center of mass 1082.

As the spool 1038 is rotated to unwind the wound cable 1086, it will move proximally along the spool spindle 1040 (e.g., from right to left as seen in FIG. 10). The spool center of mass 1082 will move towards the lateral centerline 1088, and in some cases, move past the lateral centerline 1088. As the spool 1038 rotates, the spool sprocket 1036 rotates and causes the chain 1070 to rotate the counterweight sprocket 1068, which in turn rotates the lead screw 1048 to drive the counterweight 1046 to move axially in a direction opposite the spool 1038 (e.g., the counterweight 1046 can move from left to right as seen in FIG. 10). The counterweight center of mass 1080 will move towards the lateral centerline 1088, and in some cases, move past the lateral centerline 1088. In some cases, when the spool center of mass 1082 reaches the lateral centerline 1088, the counterweight center of mass 1080 will also reach the lateral centerline 1088, although that need not always be the case.

Thus, as the spool center of mass 1082 moves with respect to the center of the cable port 1020, the counterweight center of mass 1080 moves in a corresponding, opposite direction to maintain the center of mass 1078 of the seed lift assembly 1002 in the same location (e.g., at or above the center of the cable port 1020 and/or along an axis of rotation of the seed lift assembly 1002).

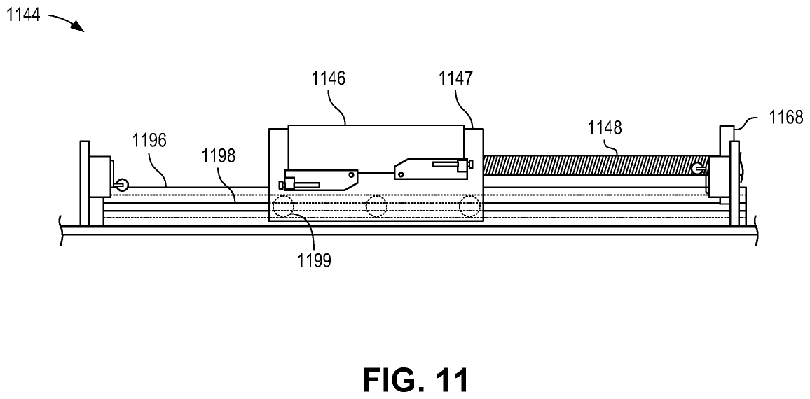

FIG. 11 is a schematic rear view of a counterweight assembly 1144, according to certain aspects of the present disclosure. Counterweight assembly 1144 is an alternate style of counterweight assembly that can be used in any suitable seed lift assembly, such as seed lift assembly 102 of FIG. 1.

Counterweight assembly 1144 can be similar to other counterweight assemblies as disclosed herein, but the counterweight 1146 can be coupled to a carriage 1147 traveling on a linear rail 1196. The counterweight 1146, carriage 1147, and rail 1196 can act as counterweights to components on an opposite side of the seed lift assembly, with the counterweight 1146 and carriage 1147 movable to compensate for movement of the spool.

Leadscrew 1148 can be coupled to carriage 1147 such that rotation of the leadscrew 1148 by counterweight sprocket 1168 will cause the carriage 1147 to move axially along the rail 1196. Rollers 1199 of the carriage 1147 can fit within a track 1198 of the rail 1196 to maintain the carriage 1147 sliding along rail 1196 with low friction. In some cases, rollers 1199 can be in the form of wheels or bearings. In some cases, the linear rail 1196 can be an extrusion with a “T”-shaped track 1198.

A counterweight 1146 can be coupled to carriage 1147. In some cases, counterweight 1146 can be coupled to the carriage 1147 in only a single location, although that need not always be the case. In some cases, the counterweight 1146 can be coupled to the carriage 1147 at multiple axial positioned (e.g., positions from left to right as seen in FIG. 11). In such cases, the counterweight 1146 can be adjusted axially with respect to the carriage 1147 to fine-tune the location of the combined center of weight of the counterweight 1146 and carriage 1147, such as with respect to the center of weight of the spool.

In some cases, rail 1196 can be replaced with two or more rails. In some cases, axial movement of the carriage 1147 can be driven using an alternate linear actuator instead of a leadscrew 1148.

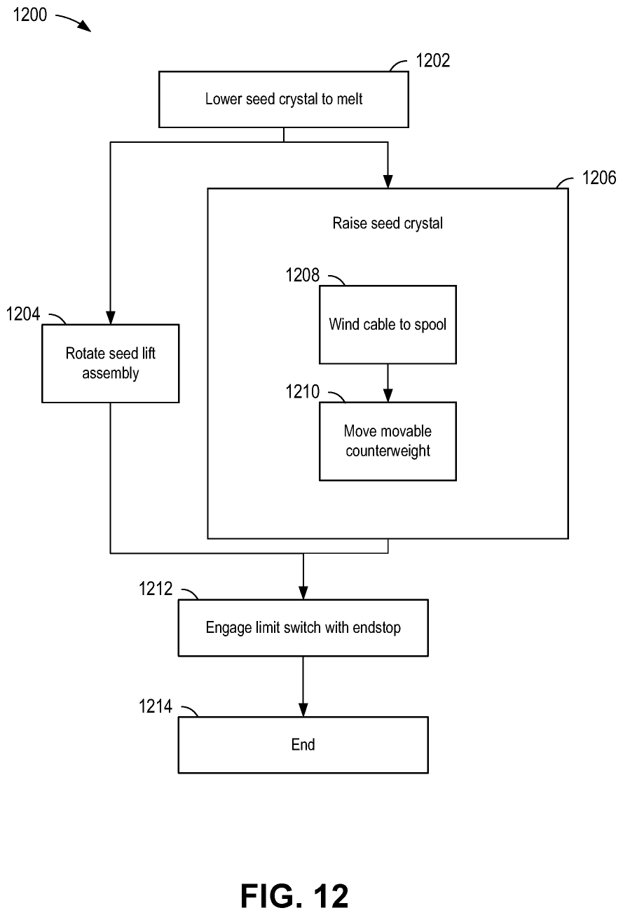

FIG. 12 is a flowchart depicting a process 1200 for actively balancing a seed lift, according to certain aspects of the present disclosure. Process 1200 can be performed by any suitable crystal growing system, such as crystal growing system 100 of FIG. 1.

At block 1202, a seed crystal is lowered to a melt. The seed crystal is attached to a cable or similar flexible support that is itself supported by a seed lift assembly. The seed crystal can be lowered to contact the melt and begin seeding crystal formation.

At block 124 and block 1206, the seed lift assembly is rotated and the seed crystal is raised, respectively. Blocks 1204 and 1206 can occur simultaneously. Rotating the seed lift assembly at block 1204 includes inducing the seed crystal to rotate with respect to the melt. In some cases, rotating the seed lift assembly at block 1204 occurs while a crucible containing the melt is rotated in an opposite direction.

Raising the seed crystal at block 1206 can include winding the cable onto a spool at block 1208. Winding the cable onto the spool at block 1208 includes axially displacing the spool, and thus axially displacing the spool's center of mass, with respect to the center of mass of the seed lift assembly. Because the spool is mechanically coupled to a movable counterweight of a counterweight assembly, winding the cable onto the spool at block 1208 also automatically causes the movable counterweight to move at block 1210. Movement of the movable counterweight at block 1210 causes the counterweight center of mass to be displaced with respect to the center of mass of the seed lift assembly in a direction opposite the axial displacement of the spool center of mass at block 1208. The displacement of the counterweight center of mass at block 1210 automatically offsets the displacement of the spool center of mass at block 1208, thus maintaining the center of mass of the seed lift assembly in place (e.g., avoiding movement of the center of mass of the seed lift assembly). Blocks 1208 and 1210 occur simultaneously.

In some cases, at optional block 1212, an endstop of the movable counterweight can engage a limit switch of the seed lift assembly (e.g., a limit switch of the counterweight assembly). When the limit switch is engaged, the system can automatically perform one or more actions. In some cases, a limit switch located at an end position of the counterweight can cause process 1200 to end at block 1214.

While process 1200 is described with reference to certain blocks in certain orders, any suitable order can be used, along with additional and/or fewer blocks. For example, in some cases process 1200 further includes engaging a limit switch as part of or after lowering the seed crystal to the melt at block 1202. In another example, in some cases process 1200 does not include engaging any limit switches with an endstop of the movable counterweight.

While described with reference to a spool winding a cable, in some cases active balancing with a mechanically coupled movable counterweight (e.g., as described with reference to block 1210) can occur for movement of a center of mass of a different component of the seed lift assembly with respect to the center of mass of the seed lift assembly.

The foregoing description of certain aspects of the present disclosure, including illustrated implementations, has been presented only for the purpose of illustration and description and is not intended to be exhaustive or limiting to the precise forms disclosed. Numerous modifications, adaptations, and uses thereof will be apparent to those skilled in the art. Numerous changes to the disclosed implementations can be made in accordance with the disclosure herein, without departing from the spirit or scope of the invention. Thus, the breadth and scope of the present invention should not be limited by any of the above described implementations.

Although the invention has been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

The terminology used herein is for the purpose of describing particular implementations only, and is not intended to be limiting of the invention. As used herein, the singular forms “a,” “an,” and “the” are intended to include the plural forms as well, unless the context clearly indicates otherwise. Furthermore, to the extent that the terms “including,” “includes,” “having,” “has,” “with,” or variants thereof, are used in either the detailed description and/or the claims, such terms are intended to be inclusive in a manner similar to the term “comprising.”

As used below, any reference to a series of examples is to be understood as a reference to each of those examples disjunctively (e.g., “Examples 1-4” is to be understood as “Examples 1, 2, 3, or 4”).

Example 1 is a seed lifting assembly comprising: a platform base having a cable port for outputting a cable supporting a seed crystal; a spool having a helical collection groove extending along a length of the spool, the spool rotatable about an axis of rotation to wind the cable into the collection groove as the spool moves longitudinally along a spool axis; and a counterweight assembly coupled to the platform base, the counterweight assembly including: a counterweight leadscrew rotatably coupled to the spool such that rotation of the spool induces rotation of the counterweight leadscrew; and a movable counterweight coupled to the counterweight leadscrew, wherein rotation of the counterweight leadscrew induces sliding of the movable counterweight along a counterweight axis that is parallel to the spool axis; and wherein, in response to longitudinal movement of the spool in a first direction, the counterweight assembly is configured to slide the movable counterweight in a direction opposite the first direction by an amount sufficient to offset any center of mass displacement induced by the longitudinal movement of the spool.

Example 2 is the assembly of example(s) 1, further comprising a spool spindle coupled to the spool to rotate the spool, wherein spool spindle includes a spool sprocket, wherein the counterweight leadscrew includes a counterweight sprocket, and wherein the counterweight leadscrew is rotatably coupled to the spool via a coupling between the spool sprocket and counterweight sprocket.

Example 3 is the assembly of example(s) 2, wherein the coupling between the spool sprocket and the counterweight sprocket includes a drive chain.

Example 4 is the assembly of example(s) 3, wherein the spool has a spool mass; wherein the cable has a cable winding mass defined as the mass of a single winding of the cable around the spool; wherein the movable counterweight has a counterweight mass; wherein a displacement ratio between a distance of longitudinal movement of the spool and a distance of sliding of the movable counterweight is defined based on the spool mass, the cable winding mass, and the counterweight mass; and wherein a gear ratio between the spool sprocket and the counterweight sprocket is based on the displacement ratio and a pitch of the counterweight leadscrew.

Example 5 is the assembly of example(s) 1-4, wherein the spool is longitudinally movable along the spool axis between a first spool position and a second spool position, wherein the movable counterweight is slidable along the counterweight axis between a first counterweight position and a second counterweight position, wherein the movable counterweight is in the first counterweight position when the spool is in the first spool position, and wherein the movable counterweight is in the second counterweight position when the spool is in the second spool position.

Example 6 is the assembly of example(s) 1-5, wherein the counterweight assembly further includes a channel having a plurality of channel walls, and wherein the movable counterweight includes a plurality of wheels slidably supporting the movable counterweight within the channel.

Example 7 is the assembly of example(s) 1-6, further comprising one or more limit switches, wherein the counterweight assembly further includes one or more endstops coupled to the movable counterweight and positioned to engage the one or more limit switches based on movement of the movable counterweight.

Example 8 is a crystal growing system, comprising: a growth chamber having a crucible containing a melt; a seed crystal suspended within the growth chamber by a cable along a cable centerline; and a seed lift assembly rotatably coupled to a top end of the growth chamber and having an assembly center of mass along the cable centerline, the seed lift assembly supporting the cable within the growth chamber, the seed lift assembly having a spool for raising the cable and having a movable counterweight, the spool having a spool center of mass that moved with respect to the cable centerline as the cable is raised, the movable counterweight having a counterweight center of mass, wherein the movable counterweight is mechanically coupled to the spool such that movement of the spool center of mass with respect to the cable centerline induces coordinated movement of the counterweight center of mass such that the assembly center of mass remains along the cable centerline.

Example 9 is the system of example(s) 8, wherein the seed lift assembly includes a plurality of structural and functional components that includes the spool, wherein the seed lift assembly further includes one or more static counterweights that do not move with respect to the cable centerline, and wherein the one or more static counterweights and the movable counterweight are sized and positioned to establish the assembly center of mass along the cable centerline.

Example 10 is the system of example(s) 8 or 9, wherein the seed lift assembly includes a spool spindle coupled to the spool to rotate the spool, wherein spool spindle includes a spool sprocket, wherein the movable counterweight is driven by a counterweight leadscrew having a counterweight sprocket, and wherein the counterweight leadscrew is rotatably coupled to the spool via a coupling between the spool sprocket and counterweight sprocket.

Example 11 is the system of example(s) 10, wherein the spool has a spool mass; wherein the cable has a cable winding mass defined as the mass of a single winding of the cable around the spool; wherein the movable counterweight has a counterweight mass; wherein a displacement ratio between a distance of longitudinal movement of the spool and a distance of sliding of the movable counterweight is defined based on the spool mass, the cable winding mass, and the counterweight mass; and wherein a gear ratio between the spool sprocket and the counterweight sprocket is based on the displacement ratio and a pitch of the counterweight leadscrew.

Example 12 is the system of example(s) 8-11, wherein the movable counterweight includes a plurality of wheels to slidably support the movable counterweight within a channel of the seed lift assembly.

Example 13 is the system of example(s) 8-12, further comprising one or more limit switches, wherein the counterweight assembly further includes one or more endstops coupled to the movable counterweight and positioned to engage the one or more limit switches based on movement of the movable counterweight.

Example 14 is a method for growing a crystal, comprising: lowering a seed crystal to a melt by a cable supported by a seed lift assembly, the cable having a cable centerline; simultaneously rotating the seed lift assembly and raising the cable, wherein raising the cable includes: raising the cable via movement of a component of the seed lift assembly, wherein movement of the component causes a center of mass of the component to be moved with respect to the cable centerline; and automatically moving a movable counterweight in response to movement of the component, wherein the movable counterweight is mechanically coupled to the component such that movement of the center of mass of the component with respect to the cable centerline is offset by movement of a counterweight center of mass to maintain a center of mass of the seed lift assembly along the cable centerline.

Example 15 is the method of example(s) 14, wherein the component is a spool, and wherein raising the cable via movement of the component includes winding the cable around the spool.

Example 16 is the method of example(s) 15, wherein the movable counterweight is moved by rotation of a counterweight leadscrew having a counterweight sprocket, wherein the spool is rotated by a spool spindle having a spool sprocket, and wherein the movable counterweight is mechanically coupled to the spool via a coupling between the counterweight sprocket and the spool sprocket.

Example 17 is the method of example(s) 16, wherein the cable has a cable winding mass defined as the mass of a single winding of the cable around the spool; wherein the movable counterweight has a counterweight mass; wherein a displacement ratio between a distance of longitudinal movement of the spool and a distance of sliding of the movable counterweight is defined based on the spool mass, the cable winding mass, and the counterweight mass; and wherein a gear ratio between the spool sprocket and the counterweight sprocket is based on the displacement ratio and a pitch of the counterweight leadscrew.

Example 18 is the method of example(s) 14-17, wherein lowering the seed crystal to the melt includes: moving the movable counterweight to a start position; and triggering a start limit switch with a start endstop coupled to the movable counterweight in response to movement of the movable counterweight to the start position.

Example 19 is the method of example(s) 14-18, further comprising: moving the movable counterweight to an end position; and triggering an end limit switch with an end endstop coupled to the movable counterweight in response to movement of the movable counterweight to the end position, wherein triggering of the end limit switch stops the raising of the cable.

Example 20 is the method of example(s) 14-19, wherein the movable counterweight includes a plurality of wheels to slidably support the movable counterweight within a channel of the seed lift assembly.

What is claimed is:

1. A seed lifting assembly comprising:
a platform base having a cable port for outputting a cable supporting a seed crystal;
a spool having a helical collection groove extending along a length of the spool, the spool rotatable about an axis of rotation to wind the cable into the collection groove as the spool moves longitudinally along a spool axis; and
a counterweight assembly coupled to the platform base, the counterweight assembly including:
a counterweight leadscrew rotatably coupled to the spool such that rotation of the spool induces rotation of the counterweight leadscrew; and
a movable counterweight coupled to the counterweight leadscrew, wherein rotation of the counterweight leadscrew induces sliding of the movable counterweight along a counterweight axis that is parallel to the spool axis; and
wherein, in response to longitudinal movement of the spool in a first direction, the counterweight assembly is configured to slide the movable counterweight in a direction opposite the first direction by an amount sufficient to offset any center of mass displacement induced by the longitudinal movement of the spool.

2. The assembly of claim 1, further comprising a spool spindle coupled to the spool to rotate the spool, wherein spool spindle includes a spool sprocket, wherein the counterweight leadscrew includes a counterweight sprocket, and wherein the counterweight leadscrew is rotatably coupled to the spool via a coupling between the spool sprocket and counterweight sprocket.

3. The assembly of claim 2, wherein the coupling between the spool sprocket and the counterweight sprocket includes a drive chain.

4. The assembly of claim 3, wherein the spool has a spool mass; wherein the cable has a cable winding mass defined as the mass of a single winding of the cable around the spool; wherein the movable counterweight has a counterweight mass; wherein a displacement ratio between a distance of longitudinal movement of the spool and a distance of sliding of the movable counterweight is defined based on the spool mass, the cable winding mass, and the counterweight mass; and wherein a gear ratio between the spool sprocket and the counterweight sprocket is based on the displacement ratio and a pitch of the counterweight leadscrew.

5. The assembly of claim 1, wherein the spool is longitudinally movable along the spool axis between a first spool position and a second spool position, wherein the movable counterweight is slidable along the counterweight axis between a first counterweight position and a second counterweight position, wherein the movable counterweight is in the first counterweight position when the spool is in the first spool position, and wherein the movable counterweight is in the second counterweight position when the spool is in the second spool position.

6. The assembly of claim 1, wherein the counterweight assembly further includes a channel having a plurality of channel walls, and wherein the movable counterweight includes a plurality of wheels slidably supporting the movable counterweight within the channel.

7. The assembly of claim 1, further comprising one or more limit switches, wherein the counterweight assembly further includes one or more endstops coupled to the movable counterweight and positioned to engage the one or more limit switches based on movement of the movable counterweight.

8. A crystal growing system, comprising:
a growth chamber having a crucible containing a melt;
a seed crystal suspended within the growth chamber by a cable along a cable centerline; and
a seed lift assembly rotatably coupled to a top end of the growth chamber and having an assembly center of mass along the cable centerline, the seed lift assembly supporting the cable within the growth chamber, the seed lift assembly having a spool for raising the cable and having a movable counterweight, the spool having a spool center of mass that moved with respect to the cable centerline as the cable is raised, the movable counterweight having a counterweight center of mass, wherein the movable counterweight is mechanically coupled to the spool such that movement of the spool center of mass with respect to the cable centerline induces coordinated movement of the counterweight center of mass such that the assembly center of mass remains along the cable centerline.

9. The system of claim 8, wherein the seed lift assembly includes a plurality of structural and functional components that includes the spool, wherein the seed lift assembly further includes one or more static counterweights that do not move with respect to the cable centerline, and wherein the one or more static counterweights and the movable counterweight are sized and positioned to establish the assembly center of mass along the cable centerline.

10. The system of claim 8, wherein the seed lift assembly includes a spool spindle coupled to the spool to rotate the spool, wherein spool spindle includes a spool sprocket, wherein the movable counterweight is driven by a counterweight leadscrew having a counterweight sprocket, and wherein the counterweight leadscrew is rotatably coupled to the spool via a coupling between the spool sprocket and counterweight sprocket.

11. The system of claim 10, wherein the spool has a spool mass; wherein the cable has a cable winding mass defined as the mass of a single winding of the cable around the spool; wherein the movable counterweight has a counterweight mass; wherein a displacement ratio between a distance of longitudinal movement of the spool and a distance of sliding of the movable counterweight is defined based on the spool mass, the cable winding mass, and the counterweight mass; and wherein a gear ratio between the spool sprocket and the counterweight sprocket is based on the displacement ratio and a pitch of the counterweight leadscrew.

12. The system of claim 8, wherein the movable counterweight includes a plurality of wheels to slidably support the movable counterweight within a channel of the seed lift assembly.

13. The system of claim 8, further comprising one or more limit switches, wherein the counterweight assembly further includes one or more endstops coupled to the movable counterweight and positioned to engage the one or more limit switches based on movement of the movable counterweight.

14. A method for growing a crystal, comprising:
lowering a seed crystal to a melt by a cable supported by a seed lift assembly, the cable having a cable centerline; and
simultaneously rotating the seed lift assembly and raising the cable, wherein raising the cable includes:
raising the cable via movement of a component of the seed lift assembly, wherein movement of the component causes a center of mass of the component to be moved with respect to the cable centerline; and
automatically moving a movable counterweight in response to movement of the component, wherein the movable counterweight is mechanically coupled to the component such that movement of the center of mass of the component with respect to the cable centerline is offset by movement of a counterweight center of mass to maintain a center of mass of the seed lift assembly along the cable centerline.

15. The method of claim 14, wherein the component is a spool, and wherein raising the cable via movement of the component includes winding the cable around the spool.

16. The method of claim 15, wherein the movable counterweight is moved by rotation of a counterweight leadscrew having a counterweight sprocket, wherein the spool is rotated by a spool spindle having a spool sprocket, and wherein the movable counterweight is mechanically coupled to the spool via a coupling between the counterweight sprocket and the spool sprocket.

17. The method of claim 16, wherein the cable has a cable winding mass defined as the mass of a single winding of the cable around the spool; wherein the movable counterweight has a counterweight mass; wherein a displacement ratio between a distance of longitudinal movement of the spool and a distance of sliding of the movable counterweight is defined based on the spool mass, the cable winding mass, and the counterweight mass; and wherein a gear ratio between the spool sprocket and the counterweight sprocket is based on the displacement ratio and a pitch of the counterweight leadscrew.

18. The method of claim 14, wherein lowering the seed crystal to the melt includes:
moving the movable counterweight to a start position; and
triggering a start limit switch with a start endstop coupled to the movable counterweight in response to movement of the movable counterweight to the start position.

19. The method of claim 14, further comprising:
moving the movable counterweight to an end position; and
triggering an end limit switch with an end endstop coupled to the movable counterweight in response to movement of the movable counterweight to the end position, wherein triggering of the end limit switch stops the raising of the cable.

20. The method of claim 14, wherein the movable counterweight includes a plurality of wheels to slidably support the movable counterweight within a channel of the seed lift assembly.
